(19) United States
(12) Patent Application Publication
(10) Pub. No.: US 2007/0004071 A1
(43) Pub. Date: Jan. 4, 2007

(54) Liquid crystal display and method for fabricating the same

(75) Inventors: Jae-young Lee, Yongin-si (KR); Won-sang Park, Yongin-si (KR); Hae-young Yun, Suwon-si (KR); Sang-woo Kim, Suwon-si (KR); Jae-ik Lim, Seoul (KR); Young-joo Chang, Suwon-si (KR); Sung-eun Cha, Geoje-si (KR); Ji-youn Choi, Suwon-si (KR); Hye-jin Seo, Suwon-si (KR); Joo-hee Oh, Suwon-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/479,085

(22) Filed: Jun. 30, 2006

(30) Foreign Application Priority Data
Jul. 1, 2005 (KR) 10-2005-0059374

(51) Int. Cl. H01L 21/00; H01L 33/00

(52) U.S. Cl. 438/30; 257/98

(57) ABSTRACT

A liquid crystal display (LCD) and a method for fabricating the same in which the pixel electrodes of a lower substrate includes sub-pixel electrodes each defining a domain and in which the upper substrate includes a common electrode having openings in a region corresponding to the center of the sub-pixel electrodes, either of both of the sub-pixel electrodes and the common electrodes inclining toward each other, and a liquid crystal layer including liquid crystal molecules formed between the lower substrate and the upper substrate.

### REFERENCE TO RELATED APPLICATION

This application claims priority from Korean Patent Application No. 10-2005-0059374 filed on Jul. 1, 2005 in the Korean Intellectual Property Office, the disclosure of which is incorporated herein by reference in its entirety.

### FIELD OF THE INVENTION

The present invention relates to a liquid crystal display (LCD), and more particularly, to an LCD having an improved response speed and a method for fabricating the LCD.

### DESCRIPTION OF THE RELATED ART

A liquid crystal display (LCD) is one of the most widely used flat panel displays. An LCD includes two substrates provided with electrodes and a liquid crystal (LC) layer interposed therebetween and adjusts the amount of light transmitted therethrough by applying a voltage to the electrodes to rearrange liquid crystal molecules in the liquid crystal layer, thereby displaying images.

LCD modes are variously classified according to the alignment and driving method of the LC molecule. Among the LCD modes, a vertical alignment (VA) mode is currently popular because it can provide a high contrast ratio and a wide reference angle. However, when a pixel electrode is divided into a plurality of domains to obtain a wide view angle, an increase in the area of the cutouts or openings leads to a reduction in aperture ratio, causing a decrease in luminance. Although the control of the movement direction of liquid crystal molecules using the cutouts or openings may be effective around the cutout, direction control over liquid crystal molecules away from the cutout is relatively ineffective. As a result, the liquid crystal molecules cannot be tilted in the desired direction, resulting in a texture problem. Moreover, because of a change in the electric field, the response time required for liquid crystal molecules to move increases, causing degradation in the response speed.

### SUMMARY OF THE INVENTION

The present invention provides a liquid crystal display (LCD) having an improved response speed in which a lower substrate includes a pixel electrode having sub-pixel electrodes, each sub-pixel electrode defining a domain. An upper substrate includes a common electrode having openings in regions corresponding to the centers of the sub-pixel electrodes. Either or both of the common electrodes and the sub-pixel electrodes may be inclined toward the centers of the sub-pixel electrodes. A liquid crystal layer including liquid crystal molecules is formed between the lower substrate and the upper substrate.

According to a further aspect of the present invention, there is provided a method for fabricating a liquid crystal display, the method including coating a lower organic layer on a lower substrate having metal wiring, forming a passivation layer in an embossing pattern where a concave portion is repeatedly formed for each domain by partially or entirely removing a portion of the lower organic layer and reflowing the lower organic layer, conformally depositing a conductive oxide layer on the passivation-layer and patterning the conductive oxide layer to form a pixel electrode including sub-pixel electrodes defining the domain, forming an overcoat layer on an upper substrate, conformally forming a common electrode including openings corresponding to the center of the sub-pixel electrodes on the overcoat layer, and combining the lower substrate facing the upper substrate with each other such that the center of the sub-pixel electrode and the openings of the common electrode overlap.

According to yet another aspect of the present invention, there is provided a method for fabricating a liquid crystal display (LCD), the method including forming a passivation layer on a lower substrate where a metal wiring is formed, conformally depositing a conductive oxide layer on the passivation layer and patterning the conductive oxide layer to form a pixel electrode including sub-pixel electrodes each defining a domain, coating an upper organic layer on an upper substrate, forming an overcoat layer in an embossing pattern where a concave portion is repeatedly formed for each domain, by partially or entirely removing a portion of the upper organic layer and reflowing the upper organic layer, conformally forming a common electrode including openings corresponding to the center of the sub-pixel electrodes on the overcoat layer, and combining the lower substrate facing the upper substrate with each other such that the center of the sub-pixel electrodes and the openings of the common electrode overlap each other.

According to a further aspect of the present invention, there is provided a method for fabricating an LCD display, the method including forming a lower layer on a lower substrate where a metal wiring is formed, forming an overcoat layer in an embossing pattern where a concave portion is repeatedly formed for each domain by partially or entirely removing a portion of the lower organic layer and reflowing the lower organic layer, conformally depositing a conductive oxide layer on the passivation layer and patterning the conductive oxide layer to form a pixel electrode including sub-pixel electrodes defining the domain, coating an upper organic layer on an upper substrate, forming an overcoat layer in an embossing pattern where a concave portion is repeatedly formed for each domain, by partially or entirely removing a portion of the upper organic layer and reflowing the upper organic layer, conformally forming a common electrode including openings corresponding to the center of the sub-pixel electrode on the overcoat layer, and combining the lower substrate facing the upper substrate with each other such that the center of the sub-pixel electrodes and the openings of the common electrode overlap each other.

### BRIEF DESCRIPTION OF THE DRAWINGS

The above and other features and advantages of the present invention will become more apparent from a reading of the ensuing description together with the drawing, in which:

FIG. 1 is a schematic plane view of a lower substrate of a liquid crystal display (LCD) according to an embodiment of the present invention;

FIG. 2 is a schematic plane view of an upper substrate of an LCD according to an embodiment of the present invention;

FIG. 3 is a schematic plane view of an LCD according to an embodiment of the present invention;

FIG. 4 is a sectional view of the LCD taken along the line IV-IV′ shown in FIG. 3;

FIG. 5 is a sectional view of the LCD taken along the line V-V′ shown in FIG. 3;

FIG. 6 is a schematic sectional view of an LCD according to another embodiment of the present invention;

FIG. 7 is a schematic sectional view of an LCD according to still another embodiment of the present invention; and

FIGS. 8A through 8H are sectional views showing processing steps of a method for fabricating an LCD according to an embodiment of the present invention.

### DETAILED DESCRIPTION

When, in the ensuing description, an element or layer may be referred to as being “on”, “connected to” or “coupled to” another element, it should be understood that it can be directly on, connected or coupled to the other element or layer or intervening elements may be present. In contrast, when an element is referred to as being “directly on,” “directly connected to” or “directly coupled to” another element, there are no intervening elements present. Like numbers refer to like elements throughout. Spatially relative terms, such as “beneath,” “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

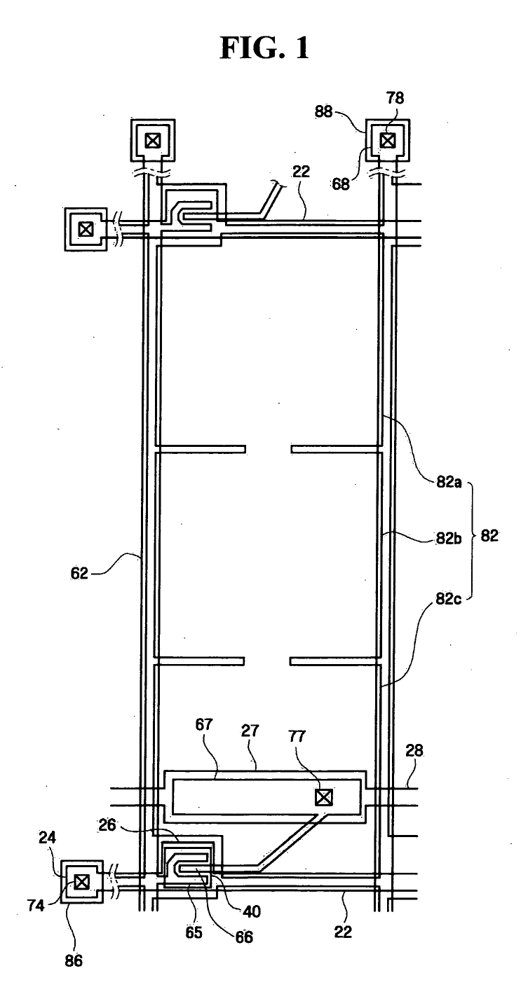

Referring to FIG. 1, the LCD of the present invention includes a lower substrate 1, an upper substrate 2 opposite to lower substrate 1, and a liquid crystal layer 3 interposed between lower substrate 1 and the upper substrate 2 and including liquid crystal molecules whose main axis is aligned nearly perpendicularly to lower substrate 1 and the upper substrate 2.

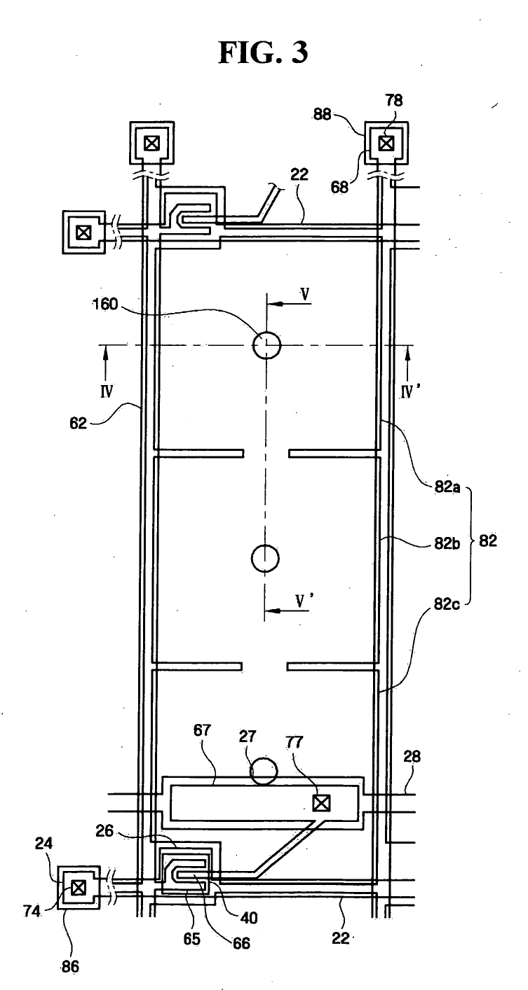

Lower substrate 1 of the LCD according to an embodiment of the present invention will be described with reference to FIGS. 1, 3 and 4. Gate wiring (22, 24, 26, 27, 28) is formed on lower insulating substrate 10 to transmit gate signals. The gate wiring includes a gate line 22 extending in a transverse direction, a gate pad 24 is formed at an end of gate line 22 to receive a gate signal from an external circuit and transmit the gate signal to gate line 22, a gate electrode 26 of a TFT connected to gate line 22 and having a shaped protrusion, a storage electrode 27 and a storage electrode line 28 formed parallel to gate line 22. Storage electrode line 28 extends in a transverse direction across a pixel area. Storage electrode 27 (shown best in FIG. 3) is wider than storage electrode line 28 and is formed at a portion of storage electrode line 28. Storage electrode 27 partially overlaps drain electrode extending portion 67 connected to a pixel electrode 82, forming a storage capacitor that increases the charge storage capability of a pixel. Storage electrode 27 and storage electrode line 28 may vary in the shape and arrangement. When the storage capacity is sufficient due to overlapping between the pixel electrode 82 and gate line 22, formation of the drain electrode extending portion 67 may be omitted.

Gate wiring (22, 24, 26, 27, 28) may include a single layer preferably made of Al, Cu, Ag, Mo, Cr, Ti, Ta, or alloys thereof. Alternatively, gate wiring (22, 24, 26, 27, 28) may have a multi-layered structure including two different conductive films (not shown) having different physical properties. In this case, one of the conductive films is preferably made of a low resistivity metal such as Al, Ag, Cu, or alloys thereof for reducing signal delay or voltage drop, and the other film is preferably made of a material that has good contact characteristics with indium tin oxide (ITO), indium zinc oxide (IZO) or similar materials such as Mo, Cr, Ti, Ta or alloys thereof. In addition, gate wiring (22, 24, 26, 27, 28) may be formed of a variety of metals or conductors but the invention is not limited thereto. Further, gate wiring (22, 24, 26, 27, 28) may have three or more layers. Gate insulating layer 30 (FIG. 5) made of silicon nitride SiNx is formed on gate wiring (22, 24, 26, 27, 28).

Semiconductor layer 40 made of hydrogenated amorphous silicon or polysilicon is formed on gate insulating layer 30. The semiconductor layer 40 may have various shapes. For example, the semiconductor layer 40 may be formed over gate electrode 26 in an island shape, like in the illustrative embodiment. In addition, the semiconductor layer 40 may be positioned below the data line 62 and extend to gate electrode 26 in a line shape.

Ohmic contact layers may be made using a material such as silicide or n+ hydrogenated amorphous silicon doped with n-type impurities at high concentration are formed on the semiconductor layer 40. The ohmic contact layers are disposed between the semiconductor layer 40 on their bottoms and a source electrode 65 and a drain electrode 66 on their tops and serve to reduce contact resistance. The ohmic contact layers may be formed in a shape of an island or line. When the ohmic contact layers are formed in a line shape, they extend below the data line 62.

Data wiring (62, 65, 66, 67, 68) is formed over the ohmic contact layers and gate insulating layer 30. The data wiring (62, 65, 66, 67, 68) includes a data line extending in a longitudinal direction and intersecting gate line 22, a source electrode 65 extending over the ohmic contact layer as a branch of the data line 62, a data pad 68, which receives data signals from another layer or from an external circuit and transmits the data signals to the data line 62, formed at one end of the data line 62, a drain electrode 66 separate from the source electrode, and a drain electrode extending portion 67 extending from the drain electrode 66 and having an wider overlapping area with storage electrode 27. The drain electrode 66 and the source electrode 65 are separate from each other and are located on the opposite sides of gate electrode 26 or a channel portion of the TFT.

Data wiring (62, 65, 66, 67, 68) may include a single layer preferably made of Al, Cu, Ag, Mo, Cr, Ti, Ta, or alloys thereof. Alternatively, the data wiring (62, 65, 66, 67, 68) may have a multi-layered structure including two different conductive films (not shown) having different physical properties. However, the invention is not limited to the specifically illustrated structures and the data wiring (62, 65, 66, 67, 68) of the present invention may have a multi-layered structure made of various metals or conductors.

Source electrode 65 overlaps at least a portion of the semiconductor layer 40. Drain electrode 66 faces source electrode 65 around gate electrode 26 and overlaps at least a portion of the semiconductor layer 40. The ohmic contact layers are positioned over semiconductor layer 40 and between source electrode 65 and drain electrode 66 and serve to reduce contact resistance therebetween.

Drain electrode extending portion 67 overlaps storage electrode 27 to form a storage capacitor with gate insulating layer 30 interposed therebetween. In the absence of storage electrode 27, formation of the drain electrode extending portion 67 is also omitted.

A passivation layer 72, which is an organic insulator, is formed on data wiring (62, 65, 66, 67, 68) and semiconductor layer 40 where not covered by data wiring (62, 65, 66, 67, 68). Passivation layer 72 has an embossed surface to receive sub-pixel electrodes 82a, 82b and 82c, such that concave portions shaped of a circular cone or a polygonal cone are consecutively formed at the respective domains. Pixel electrode 82 is formed conformally with passivation layer 72.

Contact holes 77 and 78 respectively exposing the drain electrode extending portion 67 and data pad 68 are formed in passivation layer 72. A contact hole 74 exposing gate pad 24 is formed in passivation layer 72 and gate insulating layer 30. Pixel electrode 82 electrically connected to drain electrode 66 through contact hole 77 and positioned at each pixel is formed on passivation layer 72, and an auxiliary gate pad 84 connected to gate pad 24 and an auxiliary data pad 88 connected to the data pad 68 are formed on the passivation layer 72 via the contact holes 74 and 78, respectively. Pixel electrode 82 and the auxiliary gate and data pads 86 and 88 are made of a conductive oxide layer such as ITO.

A data voltage is applied to pixel electrode 82 and generates an electric field in cooperation with common electrode 150 of the upper electrode 2, thereby determining the orientation of liquid crystal molecules 5 in liquid crystal layer 3 between pixel electrode 82 and common electrode 150. Pixel electrode 82 includes sub-pixel electrodes 82a, 82b and 82c defining domains. Here, sub-pixel electrodes 82a, 82b and 82c are tilted downward toward the center. A detailed explanation of pixel electrode 82 and sub-pixel electrodes 82a, 82b and 82c will later be given.

An alignment layer (not shown) that aligns the liquid crystal layer 3 may be formed on pixel electrode 82, the auxiliary gate and data pads 86 and 88 and the passivation layer 72. For example, as the alignment layer, a material capable of vertically aligning the liquid crystal molecules 5 may be used.

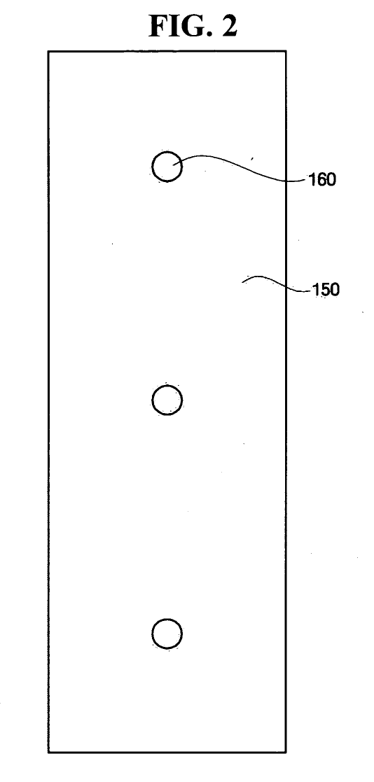

Hereinafter, the upper substrate 2 of the LCD according to the illustrative embodiment of the present invention will be described with reference to FIGS. 2 through 4. A black matrix 120 for preventing light leakage is formed on a bottom surface of an upper insulating substrate 110 made of a transparent insulating material such as glass. The black matrix 120 may be formed of an opaque material to improve picture quality by preventing light leakage. A plurality of red, green and blue color filters 130 are formed on the upper insulating substrate 110 having the black matrix 120. The color filters 130 disposed on the upper insulating substrate 110 having the black matrix 120 allow only the light having a predetermined wavelength to be selectively transmitted.

An overcoat layer 140, which is an insulating layer made of an organic material, is formed on color filters 130. Common electrode 150, which is preferably made of transparent conductive material such as ITO and IZO and has a plurality of openings 160, is formed on overcoat layer 140. Common electrode 150 will later be described in greater detail.

An alignment layer (not shown) that aligns the liquid crystal layer 3 may be formed on common electrode 150. In similar fashion to alignment layer formed on pixel electrode 82, a material capable of vertically aligning the liquid crystal molecules 5 may be used in forming the alignment layer on common electrode 150.

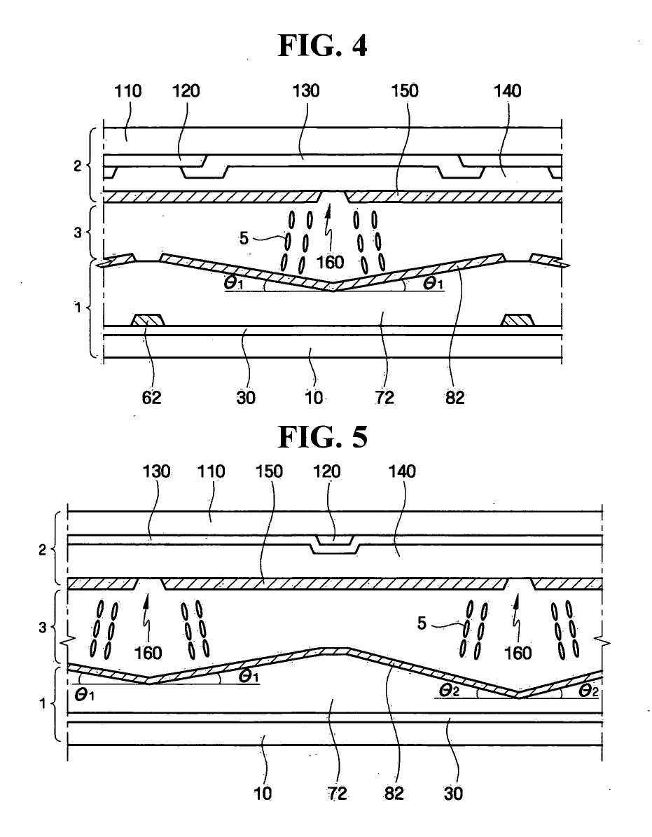

Referring to FIG. 3, openings 160 in common electrode 150 are formed at about the center of sub-pixel electrodes 82a, 82b and 82c. In this configuration as described above, (and as shown, for example, in FIG. 4) lower substrate 1 and the upper substrate 2 are aligned and coupled to each other, liquid crystal layer 3 is interposed between lower substrate 1 and upper substrate 2, and the resultant structure is vertically aligned, to provide the basic structure of the LCD.

When no voltage is applied between pixel electrode 82 and common electrode 150, the liquid crystal molecules 5 in liquid crystal layer 3 adjacent to pixel electrode 82 of lower substrate 1 have negative dielectric anisotropy and the long axes thereof are aligned perpendicularly to pixel electrode 82. The long axes of the liquid crystal molecules 5 adjacent to common electrode 150 of the upper substrate 2 are aligned perpendicularly to common electrode 150. The liquid crystal molecules 5 away from pixel electrode 82 of lower substrate 1 and common electrode 150 of the upper substrate 2 are directed midway along the long axis orientation of the peripheral liquid crystal molecules 5. Lower substrate 11 and the upper substrate 2 are aligned such that pixel electrode 82 exactly matches and overlaps the color filters 130. In this basic configuration including lower substrate 1, the upper substrate 2, and the liquid crystal layer 3, a polarizer, a backlight, and a compensation panel are further provided.

Hereinafter, pixel electrode 82 and domains of the LCD according to the illustrative embodiment of the present invention will be described in more detail with reference to FIGS. 3 and 4. Pixel electrode 82 includes sub-pixel electrodes 82a, 82b, and 82c. Sub-pixel electrodes 82a, 82b, and 82c are formed in an island shape and divide pixel electrode 82. As shown in FIG. 3, pixel electrode 82 is substantially in a rectangular shape and sub-pixel electrodes 82a, 82b, and 82c divide pixel electrode 82 in parallel with the shorter sides thereof. In pixel electrode 82, a length ratio of the shorter side to the longer side is about 1:3, which makes it suitable to implement a color image unit with three pixels.

Sub-pixel electrodes 82a, 82b, and 82c each define domains, and common electrode regions of the upper substrate 2 corresponding to sub-pixel electrodes 82a, 82b, and 82c and the liquid crystal layer 3 between sub-pixel electrodes 82a, 82b, and 82c and the common electrode regions form a single domain. Here, the common electrode regions of the upper substrate 2 corresponding to sub-pixel electrodes 82a, 82b, and 82c mean regions of common electrode 150 that are divided in the same manner as sub-pixel electrodes 82a, 82b, and 82c. When viewed from the top, the common electrode regions overlap with the corresponding sub-pixel electrodes 82a, 82b, and 82c. Here, the common electrode regions corresponding to sub-pixel electrodes 82a, 82b, and 82c are not necessarily in the same shape as one of sub-pixel electrodes 82a, 82b, and 82c. When the area of openings of common electrode 150 is disregarded, the total area of sub-pixel electrodes 82a, 82b, and 82c of lower substrate 1 is substantially larger than that of the area of common electrode 150.

Thus, the common electrode regions corresponding to sub-pixel electrodes 82a, 82b, and 82c are larger than sub-pixel electrodes 82a, 82b, and 82c. In other words, when viewed from the top, the openings 160 of common electrode 150 overlap the center of sub-pixel electrode 82a. It is preferable that the center of sub-pixel electrode 82a overlap the center of the openings 160.

For example, sub-pixel electrode 82a is tilted downward toward the center, as shown in FIG. 4. The center of sub-pixel electrode 82a is not exactly the same as the center of the gravity but is substantially symmetrical in shape. In other words, the shape of sub-pixel electrode 82a is not a perfect square, as shown in FIG. 3, but the left side of the upper side of sub-pixel electrode 82a is slightly recessed and the lower sides are connected to the next sub-pixel electrode 82b. However, a substantial basis of symmetry in the upper/lower/right/left directions may be regarded as the center of sub-pixel electrode 82a. For example, referring to FIG. 3, assuming that the shape sub-pixel electrode 82a is substantially a rectangle or square and the intersection point of diagonal lines is set to be the center of sub-pixel electrode 82a. Here, the center of sub-pixel electrode 82a does not mean a point but is a comprehensive concept covering a center point and a region in the vicinity of the center point. The center of sub-pixel electrode 82a is not so restrictively limited and it may, for example, be defined by the intersections created when an exterior side having substantially the shape of sub-pixel electrode 82a is internally divided in a ratio of 1:4 from the center point. In addition, the center of sub-pixel electrode 82a may be located at points further therefrom according to the shape of sub-pixel electrode 82a.

Common electrode 150 of upper substrate 2 has openings 160 at a region corresponding to the center of sub-pixel electrode 82a. In other words, when viewed from the top, openings 160 of common electrode 150 overlap the center of sub-pixel electrode 82a. Preferably, the center point of openings 160 overlaps the center of sub-pixel electrode 82a.

Upon application of a voltage between pixel electrode 82 and common electrode 150, a change in the electric field is created, thereby imparting directivity to the openings 160 and movement of liquid crystal molecules 5. When liquid crystal molecules 5 are placed in an electric field, they move perpendicularly to the direction of the electric field. There are numerous directions that are perpendicular to the direction of the electric field in the liquid crystal layer 3. In other words, when the electric field is perpendicular to pixel electrode 82 and common electrode 150, the liquid crystal molecules 5 may move in every direction, for example, in the backward, forward, left, right and diagonal directions. Such randomly directional movement of the liquid crystal molecules 5 causes a texture problem, degrading a display quality.

On the other hand, when the openings 160 are formed in common electrode 150, upon the application of a voltage to common electrode 150, a lateral electric field is created around the openings 160 without the voltage directly being applied to openings 160. Thus, liquid crystal molecules 5 can move toward openings 160. In other words, the liquid crystal molecules 5 in the left side of openings 160 are tilted to the right towards openings 160 and the liquid crystal molecules 5 in the right side of openings 160 are tilted to the left towards openings 160. When viewed from the top, the liquid crystal molecules 5 are tilted radially toward openings 160.

Openings 160 may be in a circular form such that domains can be symmetric around openings 160. The widths of openings 160 may be in a range that allows for a sufficient aperture ratio of an LCD while forming a lateral electric field, for example, 5-20 μm.

Although a lateral electric field is formed by openings 160 upon the application of a voltage, a relatively long response time is required until the liquid crystal molecules 5 aligned perpendicularly are attracted by the lateral electric field and are tilted towards openings 160. In particular, the liquid crystal molecules 5 away from openings 160 are insignificantly affected by the lateral electric field, so that a much longer response time may be required or the liquid crystal molecules 5 may be tilted in another direction.

To prevent such a phenomenon, sub-pixel electrode 82a is inclined downward toward the center in the current embodiment of the present invention. In other words, since sub-pixel electrode 82a is inclined downward toward the center, the liquid crystal molecules 5 aligned perpendicularly to sub-pixel electrode 82a is pre-tilted at a downward inclination angle towards the center prior to forming of an electric field by voltage application. Once the electric field is formed, the liquid crystal molecules 5 that have been pre-tilted towards the center, i.e., in the direction of openings 160, can be rapidly tilted towards openings 160 by the lateral electric field formed by openings 160. In addition, a possibility of the liquid crystal molecules 5 away from openings 160 being tilted in the pre-tilted direction also increases. As a result, the response speed of the liquid crystal molecules 5 are improved, contributing to improvement of the response speed and display quality of an LCD.

The inclination angle of sub-pixel electrode 82a may be greater than or equal to 5 degrees for a sufficient pre-tilt of the liquid crystal molecules 5. In addition, for a sufficient contrast ratio, the inclination angle of sub-pixel electrode 82a may be less than or equal to 30 degrees, preferably in a range of about 8-15 degrees.

For the same directivity of the liquid crystal molecules 5, the liquid crystal molecules 5 need to be pre-tilted at the same angle with respect to the center of sub-pixel electrode 82a. Thus, it is preferable that the inclination angle of sub-pixel electrode 82a be the same in any direction when viewed from the center of sub-pixel electrode 82a. In other words, the inclination angle of sub-pixel electrode 82a needs to be the same regardless of a cross-sectional cut direction of sub-pixel electrode 82a including the center of sub-pixel electrode 82a. Here, the same inclination angle means inclination angles in substantially the same range.

Referring to FIG. 5, the phrase “the same inclination angle” used herein is intended to mean that the inclination angles are the same at all directions of sub-pixel electrode 82a and the inclination angles of all sub-pixel electrodes 82a, 82b, and 82c included in pixel electrode 82 need not necessarily be the same. In other words, the same inclination angle for each domain satisfies the inclination angle requirement meant by the phrase recited above, and an inclination angle θ₁ of sub-pixel electrode 82a may be greater than an inclination angle θ₂ of sub-pixel electrode 82b, as shown in FIG. 5.

Referring back to FIG. 3, connection portions are formed between the adjacent sub-pixel electrodes 82a and 82b and 82b and 82c to electrically connect the adjacent sub-pixel electrodes 82a and 82b and 82b and 82c. Thus, the same voltage is applied to sub-pixel electrodes 82a, 82b, and 82c. In FIG. 3, three domains are formed by the three sub-pixel electrodes 82a, 82b, and 82c. In particular, when the shorter side and the longer side of pixel electrode 82 substantially in a rectangular shape has a ratio of about 1:3 in length and pixel electrode 82 is divided into three sub-pixel electrodes 82a, 82b, and 82c in parallel with its shorter side, sub-pixel electrodes 82a, 82b, and 82c each substantially have a rectangular shape. When sub-pixel electrodes 82a, 82b, and 82c each have a rectangular shape, all directions are symmetric with respect to openings 160. Thus, uniform reaction of the liquid crystal molecules 5 for each domain can be obtained. However, the number of sub-pixel electrodes is not limited to the illustrated example and pixel electrode 82 may be divided into two sub-pixel electrodes to form two domains or divided into at least four sub-pixel electrodes. If necessary, pixel electrode 82 is not divided so that pixel electrode 82 serves as a sub-pixel electrode and a single domain exists.

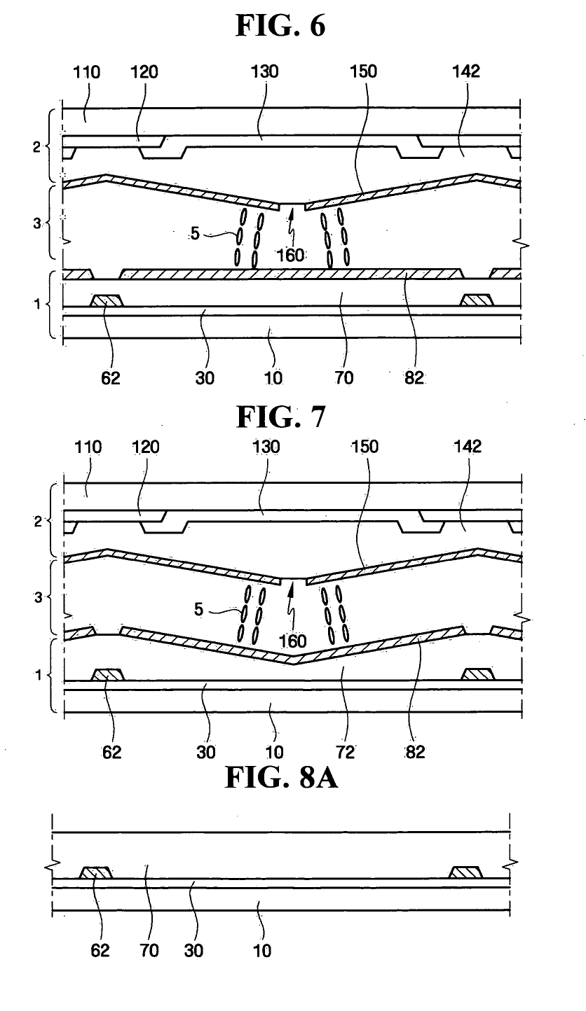

Referring to FIG. 6, an LCD according to another embodiment of the present invention will be described. The LCD according to the current embodiment of the present invention is basically the same as the LCD according to the previous embodiment of the present invention except that a common electrode region corresponding to a sub-pixel electrode is inclined downward. Therefore, a detailed explanation of repeated portions will not be given and only characteristic features of the current embodiment of the present invention will be described.

As shown in FIG. 6, a sub-pixel electrode 82a and a passivation layer 70 disposed under sub-pixel electrode 82a are not inclined but are planar. On the other hand, a common electrode region corresponding to sub-pixel electrode 82a is the same as the embodiment of FIG. 4 in that openings 160 are formed in a region corresponding to sub-pixel electrode 82a, but is different from the embodiment of FIG. 4 in that the common electrode region is inclined downward toward openings 160. Through the downward inclination, the liquid crystal molecules 5 can be pre-tilted and rapidly tilted toward openings 160 when a voltage is applied in the same manner as in the embodiment shown in FIG. 4. The inclination angle of common electrode 150 in the current embodiment of the present invention may be the same as that of sub-pixel electrode 82a in the embodiment of FIG. 4. Like a passivation layer 72 in the embodiment of the present invention, an overcoat layer 142 on common electrode 150 may be in an embossing pattern where a concave portion in a cone or polypyramidal shape is repeatedly formed for each domain in the bottom. Common electrode 150 is conformally formed under the overcoat layer 142. Although only a single domain formed by the single sub-pixel electrode 82a and the common electrode region corresponding to the same is shown in FIG. 6, the above description is also applied to other sub-pixel electrodes included in the same pixel electrode and other domains formed by sub-pixel electrodes.

An LCD according to still another embodiment of the present invention will be described with reference to FIG. 7. In the LCD according to still another embodiment of the present invention, both a sub-pixel electrode and a common electrode region corresponding to the sub-pixel electrode are inclined downward. Repeated parts of the embodiments of FIGS. 4 and 6 will not be described and only characteristic features of the current embodiment of the present invention will be described. In FIG. 7, since both sub-pixel electrode 82a and the common electrode region corresponding to sub-pixel electrode 82a are inclined downward, both the liquid crystal molecules 5 adjacent to sub-pixel electrode 82a and the liquid crystal molecules 5 adjacent to common electrode 150 are pre-tilted. Thus, an increased response time of the liquid crystal molecules 5 can be obtained. The inclination angle of sub-pixel electrode 82a and the inclination angle of common electrode 150 are not necessarily the same and only the conditions for the inclination angle described above need to be satisfied. Although only a single domain formed by the single sub-pixel electrode 82a and the common electrode region corresponding to the same is shown in FIG. 7, the same description as above hold true for the other sub-pixel electrodes included in the same pixel electrode and other domains formed by the sub-pixel electrodes.

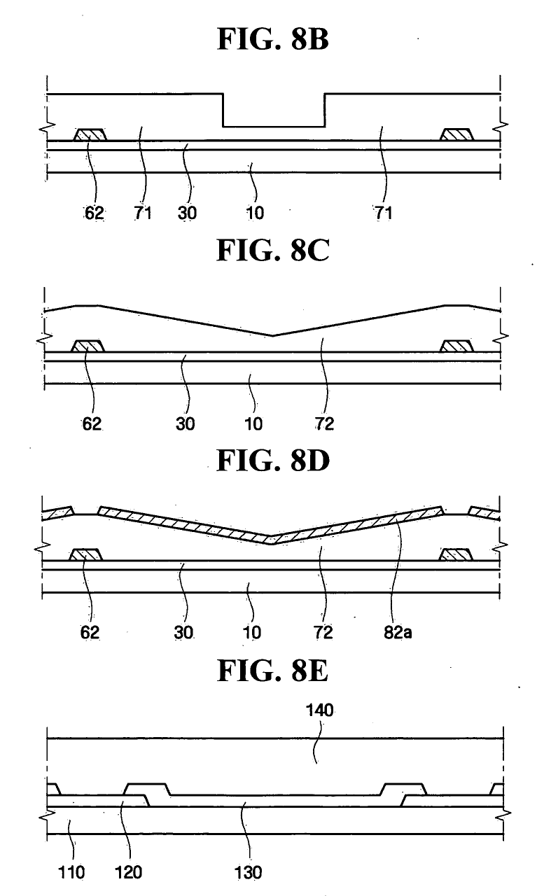

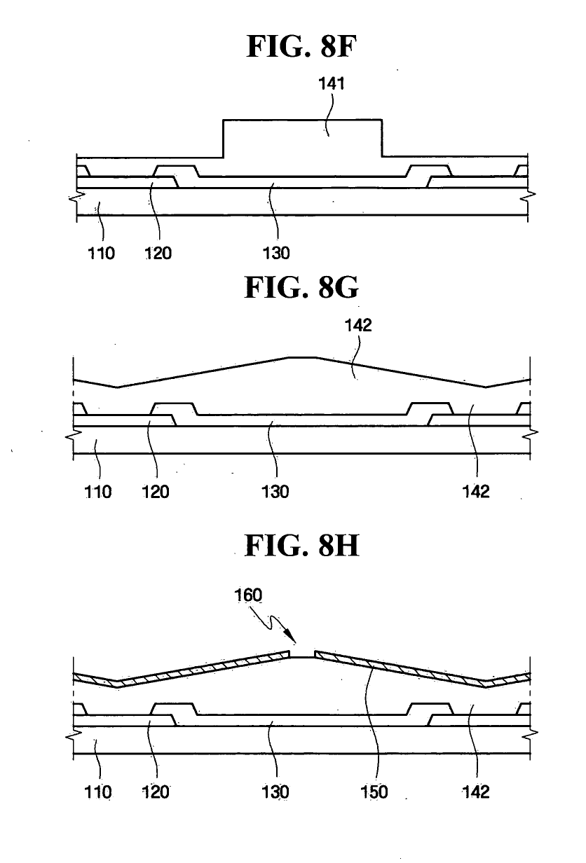

Hereinafter, a method for fabricating the LCD will be described with reference to FIGS. 7 and 8A through 8F. For clarity and convenience of explanation, a description regarding the method for fabricating the LCD of FIG. 7 where both a sub-pixel electrode and a common electrode region corresponding to the sub-pixel electrode are inclined downward will substitute for a description of methods for fabricating LCDs according to other embodiments of the present invention.

Referring to FIG. 8A, a gate wiring is formed by depositing a conductive material on a lower insulating substrate 10 and patterning the same. Next, a gate insulating layer 30 is deposited on gate wiring. After a semiconductor layer made of a semiconductor such as hydrogenated amorphous silicon or polycrystalline silicon and an ohmic contact layer made of a material such as silicide or n+ hydrogenated amorphous silicon doped with high concentration n-type impurity are deposited, both the semiconductor layer and the ohmic contact layer are simultaneously etched to form a semiconductor layer and an ohmic contact layer in an island shape. Next, a conductive material is deposited on gate insulating layer 30 and the ohmic contact layer and is patterned, thereby forming data wiring including a data line 62. Although the semiconductor layer and the ohmic contact layer, and the data line are patterned using different masks, they may be patterned using the same mask. In this case, the semiconductor layer and the ohmic contact layer may be formed in a linear shape extending below the data line 62. Next, an organic material having transparent photosensitivity is coated, thereby forming a passivation layer 70 that is a lower organic layer.

Referring to FIG. 8B, a contact hole exposing a portion of gate line or the data line is formed on passivation layer 70 using a photomask. Next, slit or halftone exposure is performed using a photomask defining a photosensitive layer pattern. In the slit or halftone exposure, the center of a sub-pixel electrode to be defined, including a mid portion between two data lines 62 and a relatively large area in the vicinity of the mid portion, is partially removed. In the partially removing step, the width and depth of the area that is partially removed are adjusted such that a passivation layer 71 reflows in a subsequent reflow process to have an appropriate inclination angle. For example, an area of less than a half a distance ranging from the center of the sub-pixel electrode to the peripheral portion thereof may be removed. Also, the passivation layer 71 may be entirely removed. Here, full exposure, rather than slit or halftone exposure, may be performed using a common photomask. In this case, the removed area may be a region of less than about ⅓ a distance from the center of the sub-pixel electrode, thereby leaving the passivation layer 71 in the center to some extent.

Referring to FIG. 8C, passivation layer 71 is subjected to reflow by being heated. If passivation layer 71 is heated at a temperature higher than the glass temperature of an organic material of passivation layer 71, mobility of the organic material is enhanced, so that the organic material flows into and fills the partially or entirely removed area of the passivation layer. At this time, there exists a downward inclination in which a height of passivation layer 71 in the center of passivation layer 71 is smaller than a height of passivation layer 71 in the region from which passivation layer 71 is partially or entirely removed. When the reflow occurs symmetrically into the region where passivation layer 71 is removed, passivation layer 72 having the same inclination angle can be formed in a single sub-pixel electrode region. When viewed in terms of the entire lower substrate, an embossing pattern having repeated concave portions in a circular cone or a polygonal cone is formed for each domain.

The formation of the contact hole and the partial or entire removal of the passivation layer may be performed separately using different masks. In this case, exposure is performed separately using different masks and development can be simultaneously performed. In addition, the formation of the contact hole and the partial or entire removal of the passivation layer may be simultaneously performed using a single mask. In this case, it is preferable that a mask region defining the removal region of the passivation layer except for the contact hole include a slit or a semi-transparent portion. In a region exposed by a slit or a semi-transparent portion, the strength and time of exposure may be adjusted so that only a portion of the passivation layer is removed. Moreover, the contact hole may be formed after an embossing forming process where the passivation layer is partially or entirely removed and is subjected to reflow.

Referring to FIG. 8D, a pixel electrode including sub-pixel electrode 82a, an auxiliary gate terminal, and a data terminal, is formed by conformally depositing a conductive oxide layer such as indium titanium oxide (ITO) on passivation layer 72 inclined downward toward the center by reflow and patterning the same. In this way, lower substrate 10 including a pixel electrode including sub-pixel electrode 82a tilted downward toward the center is completed.

Referring to FIG. 8E, a black matrix 120 is formed by deposited an opaque material on the upper insulating substrate 110 and patterning the same. Next, a color filter 130 is formed on the upper insulating substrate 110 where the black matrix 120 is formed. The formation of the color filter 130 may be performed using photolithography. At this time, to form the color filter 130 having three colors of red, green, and blue, photolithography is performed three times. Next, an organic material having photosensitivity is coated, thereby forming an overcoat layer 140 that is an upper organic layer.

Referring to FIG. 8F, in similar fashion to the passivation layer of the lower substrate, slit or halftone exposure is performed to partially or entirely remove a relatively large area outside a domain of an overcoat layer. The width and depth of a removed area are adjusted such that an overcoat layer 141 adjacent to a black matrix 120 is subject to reflow in a subsequent reflow process to have an appropriate inclination angle. For example, an area of greater than a half a distance ranging from the center of a common electrode area corresponding to a sub-pixel electrode area, that is, a mid point between one black matrix 120 and another black matrix 120 adjacent to the one black matrix 120 to the black matrix 120, may be removed. Also, the overcoat layer of the removed area may be entirely removed. Here, full exposure, rather than slit or halftone exposure, may be performed using a common photomask. In this case, the removed area may be a region of less than about ⅔ a distance from the center of the sub-pixel electrode, thereby leaving the black matrix 120 in the center to some extent.

Referring to FIG. 8G, an overcoat layer 141 reflows by being heated. Thus, the organic material is filled in a region adjacent to the black matrix 120 where the overcoat layer is partially or entirely removed, thereby forming the overcoat layer 142 having a specific inclination. When the upper insulating substrate 110 is directed downward and is viewed from the top, an embossing pattern having repeated concave portions in a cone or polypyramidal shape is formed.

Referring to FIG. 8H, a conductive oxide layer such as ITO is conformally deposited on the overcoat layer 142 repeatedly inclined by reflow and is patterned, thereby forming common electrode 150 including openings 160. At this time, the positions of openings 160 may be in the center between the adjacent black matrices 140. It is preferable that the positions of openings 160 be around the highest vertex of the overcoat layer 140 when the upper insulating substrate 110 is directed downward and openings 160 be formed in a position overlapping with the center of the sub-pixel electrode. Thus, the upper substrate 2 including common electrode 150 having openings 160 is completed.

Next, referring to FIG. 7, lower substrate 1 and the upper substrate 2 facing lower substrate 1 are combined with each other. At this time, openings 160 of common electrode 150 of the upper substrate 2 overlap with the center of sub-pixel electrode 82a of lower substrate 1. Next, the liquid crystal molecules 5 are injected between lower substrate 1 and the upper substrate 2 to form the liquid crystal layer 3 and sealing is performed. Thus, a liquid crystal panel including lower substrate 1, the upper substrate 2, and the liquid crystal layer 3 is completed, followed by attaching a polarizing film and installing a backlight, thereby completing an LCD.

Although the method for fabricating the LCD of FIG. 7 has been described in detail, the LCDs shown in FIGS. 4 and 6 can be easily manufactured by applying the method described with reference to FIGS. 8A through 8H. In other words, the LCD of FIG. 4 can be manufactured by skipping the processes of partially or entirely removing a specific region of the overcoat layer 140 of the upper substrate 2 and reflowing. The LCD of FIG. 6 can be manufactured by skipping processes of partially or entirely removing a specific region of passivation layer 72 of lower substrate 1 and reflowing.

Although transmissive LCDs have been described in the embodiments of the present invention by way of example, the present invention can also be applied to, but not limited to, a semi-transmissive or reflective LCD. Moreover, in the above described embodiments, a color filter and a black matrix formed on an upper substrate are shown. However, the present invention can also be applied to a case where the color filter and the black matrix are formed on a lower substrate. In other words, an LCD including a sub-pixel electrode tilted downward and/or a common electrode having openings inclined downward and a method for fabricating the LCD fall within the range of the present invention regardless of variations of other components.

As described above, in LCDs according to embodiments of the present invention, since sub-pixel electrodes of a lower substrate and a common electrode of an upper substrate corresponding to the sub-pixel electrodes and having openings are inclined downward, aligned liquid crystal molecules are pre-tilted, thereby improving a response speed. In addition, luminance is improved using openings in a circular form having a relatively small area.

In concluding the detailed description, those skilled in the art will appreciate that many variations and modifications can be made to the preferred embodiments without substantially departing from the principles of the present invention.

What is claimed is:

1. A liquid crystal display (LCD) comprising:
a lower substrate including a pixel electrode having sub-pixel electrodes each defining a domain, the center of each said sub-pixel electrode being inclined toward said lower substrate;
an upper substrate including a common electrode having openings in a region corresponding to the center of the sub-pixel electrodes; and
a liquid crystal layer including liquid crystal molecules formed between the lower substrate and the upper substrate.

2. The LCD of claim 1, wherein the liquid crystal molecules in the domain are pre-tilted toward the opening of the common electrode.

3. The LCD of claim 1, wherein the inclination angle of said sub-pixel electrode with respect to said lower substrate is substantially uniform over a vertical cross section through the center of the sub-pixel electrode, regardless of the orientation of the vertical cross section.

4. The LCD of claim 3, wherein the inclination angle of the sub-pixel electrode is in a range of 5-30 degrees downward toward the bottom of said lower substrate.

5. The LCD of claim 1, wherein the pixel electrode is of substantially rectangular shape.

6. The LCD of claim 5, wherein the pixel electrode includes three sub-pixel electrodes.

7. The LCD of claim 5, wherein the sub-pixel electrode is shaped of substantially a regular square.

8. The LCD of claim 1, wherein the opening in said common electrode is substantially circular in shape.

9. The LCD of claim 1, wherein the widths of the openings in said common electrode are in a range of 5-20 μm.

10. The LCD of claim 1, wherein the lower substrate further comprises a lower passivation layer having an inclination angle that is substantially the same as the inclination angle of the sub-pixel electrode.

11. The LCD of claim 10, wherein the passivation layer includes an organic material having photosensitivity.

12. A liquid crystal display (LCD) comprising:
a lower substrate including a pixel electrode having sub-pixel electrodes each defining a domain;
an upper substrate having a common electrode including openings in a region corresponding to the center of the sub-pixel electrodes; said common electrode being inclined in the region of said openings; and
a liquid crystal layer including liquid crystal molecules formed between the lower substrate and the upper substrate.

13. The LCD of claim 12, wherein the liquid crystal molecules in the domain are pre-tilted toward the openings of the common electrode.

14. The LCD of claim 12, wherein the downward inclination angle of said common electrodes with respect to said lower substrate is substantially uniform over a vertical cross section through the center of opening of the common electrode, regardless of orientation of the vertical cross section.

15. The LCD of claim 14, wherein the inclination angle of the common electrode is in a range of 5-30 degrees.

16. The LCD of claim 12, wherein the upper substrate further comprises an upper overcoat layer having an inclination angle that is substantially the same as the inclination angle of the common electrode.

17. The LCD of claim 21, wherein the overcoat layer includes an organic material having photosensitivity.

18. A liquid crystal display (LCD) comprising:
a lower substrate including a pixel electrode having sub-pixel electrodes each defining a domain downward inclined toward the center thereof;
an upper substrate including openings in a region corresponding to the center of the sub-pixel electrodes and a common electrode whose region corresponding to the sub-pixel electrode is downward inclined toward the openings; and
a liquid crystal layer including liquid crystal molecules formed between the lower substrate and the upper substrate.

19. The LCD of claim 18, wherein the lower substrate further comprises a lower passivation layer having an inclination angle that is substantially the same as the inclination angle of the sub-pixel electrode.

20. A method for fabricating a liquid crystal display, the method comprising:
coating a lower organic layer on a lower substrate where a metal wiring is formed;
forming a passivation layer in an embossing pattern where a concave portion is repeatedly formed for each domain, by partially or entirely removing a portion of the lower organic layer and reflowing the lower organic layer;
conformally depositing a conductive oxide layer on the passivation layer and patterning the conductive oxide layer to form a pixel electrode including sub-pixel electrodes defining the domain;
forming an overcoat layer on an upper substrate;
conformally forming a common electrode including openings corresponding to the center of the sub-pixel electrodes on the overcoat layer; and
combining the lower substrate facing the upper substrate with each other such that the center of the sub-pixel electrode and the openings of the common electrode overlaps.

21. A method for fabricating a liquid crystal display, the method comprising:
forming a passivation layer on a lower substrate where a metal wiring is formed;
conformally depositing a conductive oxide layer on the passivation layer and patterning the conductive oxide layer to form a pixel electrode including sub-pixel electrodes each defining a domain;
coating an upper organic layer on an upper substrate;
forming an overcoat layer in an embossing pattern where a concave portion is repeatedly formed for each domain, by partially or entirely removing a portion of the upper organic layer and reflowing the upper organic layer;
conformally forming a common electrode including openings corresponding to the center of the sub-pixel electrodes on the overcoat layer; and
combining the lower substrate facing the upper substrate with each other such that the center of the sub-pixel electrodes and the openings of the common electrode are overlapped with each other.

22. A method for fabricating a liquid crystal display (LCD), the method comprising:
forming a lower layer on a lower substrate where a metal wiring is formed;
forming an overcoat layer in an embossing pattern where a concave portion is repeatedly formed for each domain, by partially or entirely removing a portion of the lower organic layer and reflowing the lower organic layer;
conformally depositing a conductive oxide layer on the passivation layer and patterning the conductive oxide layer to form a pixel electrode including sub-pixel electrodes defining the domain;
coating an upper organic layer on an upper substrate;
forming an overcoat layer in an embossing pattern where a concave portion is repeatedly formed for each domain, by partially or entirely removing a portion of the upper organic layer and reflowing the upper organic layer;
conformally forming a common electrode including openings corresponding to the center of the sub-pixel electrode on the overcoat layer; and
combining the lower substrate facing the upper substrate with each other such that the center of the sub-pixel electrodes and the openings of the common electrode are overlapped with each other.
